(19) United States
(12) Patent Application Publication
(10) Pub. No.: US 2017/0287555 A1
(43) Pub. Date: Oct. 5, 2017

(54) RESISTIVE RANDOM ACCESS MEMORY CELL HAVING BOTTOM-SIDE OEL LAYER AND/OR OPTIMIZED ACCESS SIGNALING

(71) Applicant: INTEL CORPORATION, SANTA CLARA, CA (US)

(72) Inventors: HUICHU LIU, San Jose, CA (US); SASIKANTH MANIPATRUNI, Portland, OR (US); IAN A. YOUNG, Portland, OR (US); TANAY KARNIK, Portland, OR (US); DANIEL H. MORRIS, Hillsboro, OR (US); KAUSHIK VAIDYANATHAN, Sunnyvale, CA (US)

(21) Appl. No.: 15/088,080

(22) Filed: Mar. 31, 2016

(51) Int. Cl. G11C 13/00; H01L 45/00; H01L 27/24

(52) U.S. Cl. CPC G11C 13/003; G11C 13/004; G11C 13/0007; G11C 13/0097; H01L 27/2436; H01L 45/145

(57) ABSTRACT

An apparatus is described that includes a resistive random access memory cell having a word line that is to receive a narrowed word line signal that limits an amount of time that an access transistor is on so as to limit the cell's high resistive state and/or the cell's low resistive state. Another apparatus is described that includes a resistive random access memory cell having SL and BL lines that are to receive respective signals having different voltage amplitudes to reduce source degeneration effects of the resistive random access memory cell's access transistor. Another apparatus is described that includes a resistive random access memory cell having a storage cell comprising a bottom-side OEL layer. Another apparatus is described that includes a resistive random access memory cell having a storage cell within a metal layer that resides between a pair of other metal layers where parallel SL and BL lines of the resistive random access memory cell respectively reside.

### BACKGROUND OF THE INVENTION

The emergence of mobile devices has created keen interest amongst non volatile semiconductor memory manufacturers to increase the densities of their devices. Generally, mobile devices do not make use of disk drives in favor of semiconductor based non volatile storage devices. Historically, however, semiconductor storage devices do not have the same storage density as disk drives.

In order to bring the storage densities of semiconductor memories closer to or beyond disk drives, non volatile memory device manufacturers are developing three dimensional memory technologies. In the case of three dimensional memory technologies, individual storage cells are vertically stacked on top of another within the storage device. Three dimensional memory devices may therefore provide a mobile device with disk drive like storage density in a much smaller package, cost and power consumption envelope. However, the manufacture of three dimensional memory devices raises new manufacturing technology challenges.

Additionally, many computing system designers, both mobile and larger system alike, are looking to replace standard system memory technology (DRAM) with new, emerging non volatile memory technologies in the system memory of their computing systems.

### BRIEF DESCRIPTION OF THE DRAWINGS

The present invention is illustrated by way of example and not limitation in the figures of the accompanying drawings in which like references indicate similar elements.

FIGS. 1a through 1c (prior art) show a resistive random access memory cell;

FIG. 2 (prior art) shows a resistive random access memory cell storage structure;

FIG. 3 shows hysteresis curves of a resistive random access memory cell storage structure;

FIGS. 4a and 4b show improved resistive random access memory cells having an OEL layer toward the top of the storage structure;

FIG. 5a shows random access memory cell storage structure having an OEL layer toward the bottom of the structure;

FIGS. 5b and 5c show improved resistive random access memory cells having an OEL layer toward the bottom of the storage structure;

FIGS. 6a and 6b show an improved layout design for a resistive random access memory cell;

FIG. 7 shows an embodiment of a computing system.

### DETAILED DESCRIPTION

One type of emerging non volatile memory is resistive random access memory (RRAM). In the case of RRAM, a small resistive element is SET to a first (e.g., low) resistance or RESET to a second (e.g., high) resistance. The different resistances are interpreted as different binary values. For instance, during a read operation, a voltage may be applied across or a current may be driven through the resistive element. A sense circuit detects the resulting current or voltage to determine whether the resistive element is in a high resistance state or a low resistance state. The former, e.g., may be interpreted to be a logic “0” and the later may be interpreted to be a logic “1”.

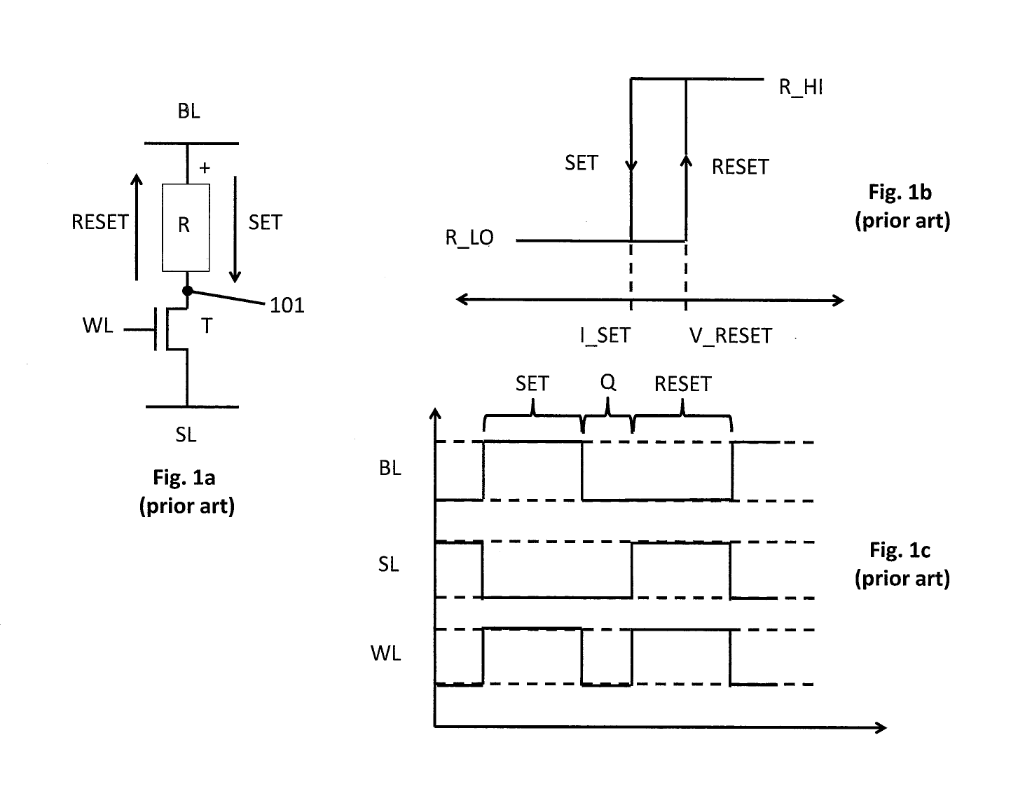

FIGS. 1a through 1c explore a prior art RRAM cell in more detail. Referring to FIGS. 1a and 1c, a SET operation will take place when the gate voltage of an NMOS transistor T is set to a logic high (the gate node is coupled to a word line WL in the memory cell), a bit line (BL) is set to a logic high and a select line (SL) is set to a logic low. With WL being a logic high, the access transistor T is “on”. Additionally, with BL being greater than SL, a current will flow through the resistive element R in a first direction from SL to BL.

According to at least one type of RRAM approach, as observed in FIG. 1b, the aforementioned SET operation causes the resistive element R to reach a low resistance state R_LO. As observed in FIG. 1c, after the SET operation, the memory cell may reach a quiescent state Q in which all three nodes WL, BL, SL are set to a logic low. In this state the resistive element holds its low resistance state and may be read one or more times to interpret its corresponding logic value. In order to read the device WL may be raised high and, as discussed above, a voltage may be applied across or a current may be driven through the resistive element R.

Subsequently, a RESET operation may take place to write the opposite value into the resistive element R. As observed in FIG. 1c, again WL is raised to a logic high, but unlike the SET operation, SL is raised to a logic high and BL is kept at a logic low. With WL at a logic high, the access transistor T will be “on” and, as observed in FIG. 1a, a current will flow in a second direction from SL to BL. As observed in FIG. 1b, these RESET conditions will cause the resistive element to “flip” to a high resistance state R_HI.

Note that during the RESET operation when current flows in the second direction toward the BL line, the channel node 101 of the access transistor T that is directly tied to the resistive element effectively behaves as the source of the access transistor T. As such, the gate-to-source voltage that is sustained by the access transistor is V_WL−V_RESET where V_WL is the logic high voltage that is applied to the gate of the access transistor T and V_RESET is the voltage drop across the resistive element R. The voltage drop V_RESET across the resistive element R is a function of the current that flows through the resistive element R and the resistance of the resistive element R.

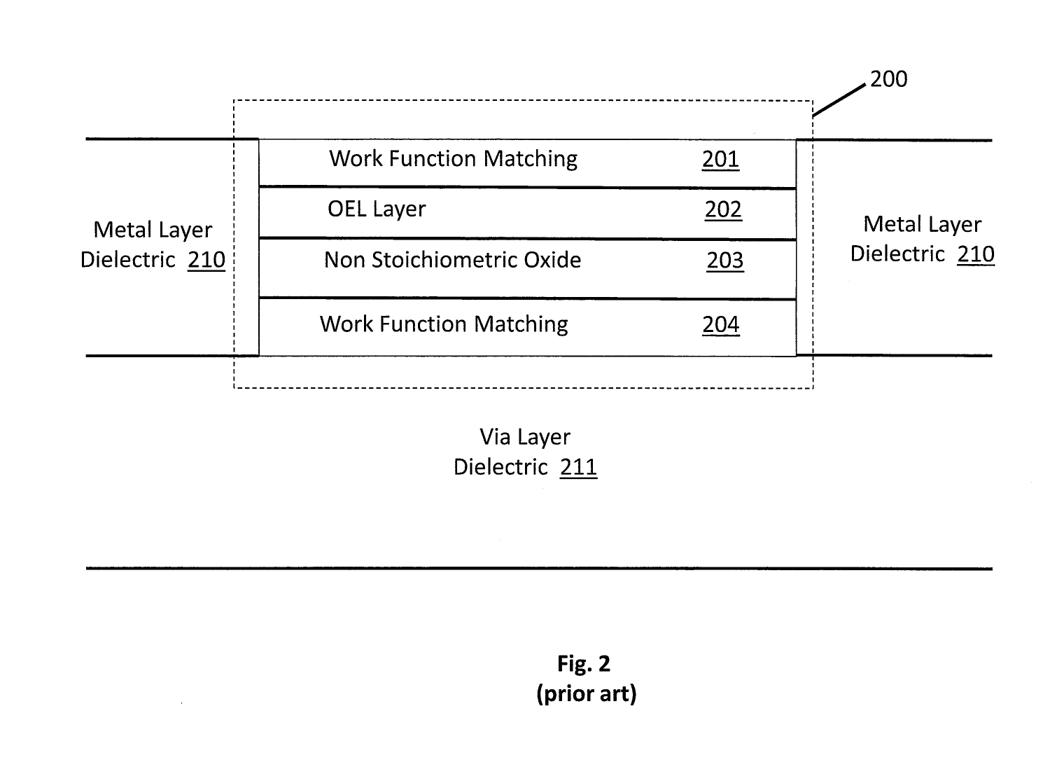

FIG. 2 shows an embodiment of a prior art resistive element 200. As is understood in the art, semiconductor chip interconnects are formed by alternating layers of conducting material (metal) and dielectric. The metal layers are patterned to form wiring structures. The patterning of a metal layer includes etching the metal layer in order to form the wires and then surrounding them with dielectric material that is disposed in the regions of etched metal. In standard CMOS processes, the lowest, transistor layer has the smallest feature size. In prior art RRAM approaches, the resistive element is processed across multiple lower metal and multiple lower dielectric layers, or resides across just one upper metal or dielectric layer. FIG. 2 shows a depiction of the later approach in which the RRAM cell is formed in an upper metal layer surrounded by the dielectric 210 that is formed in the upper metal layer.

Wires on different planes often need to be electrically connected. As such, holes are etched into the dielectric material that is disposed between neighboring metal layers. The holes are filled with metal to create vias or plugs that connect wiring formed on different metal layers. The dielectric between neighboring metal layers into which vias/plugs are formed may be referred to as a via layer dielectric 211.

As observed in the prior art approach of FIG. 2, the resistive element 200 is formed as a multi-layer structure 200 within dielectric of the metal layer 210 and not the via layer dielectric 211. Additionally, an oxide exchange layer (OEL) 202 is observed to reside toward the top of the structure. Although not shown, a barrier layer may be formed between the top work function and OEL layers 201/202 and/or between the non stoichiometric oxide and lower work function layers 203/204 depending on the interconnect materials that are used. In various embodiments the OEL layer 202 is composed of Tantalum (Ta), Tantalum Oxide (TaOx), Hafnium (Hf) or Hafnium Oxide (HfOx). Additionally, the non stoichiometric oxide layer 203 is composed of Hafnium Oxide (HfOx), Hafnium Tantalum Oxide (HfTaOx), Hafnium Aluminum Oxide (HfAlOx) or other combinations of transition metal oxides.

The prior art RRAM device 200 discussed above has a number of problems that can be improved upon. A first problem is the tendency to “overwrite” the resistive element with too much current during a SET operation or too much voltage during a RESET operation. Here, excessive energy applied to the resistive element can cause the resistive element to exhibit excessively high resistance in the R_HI state or excessively low resistance in the R_LO state.

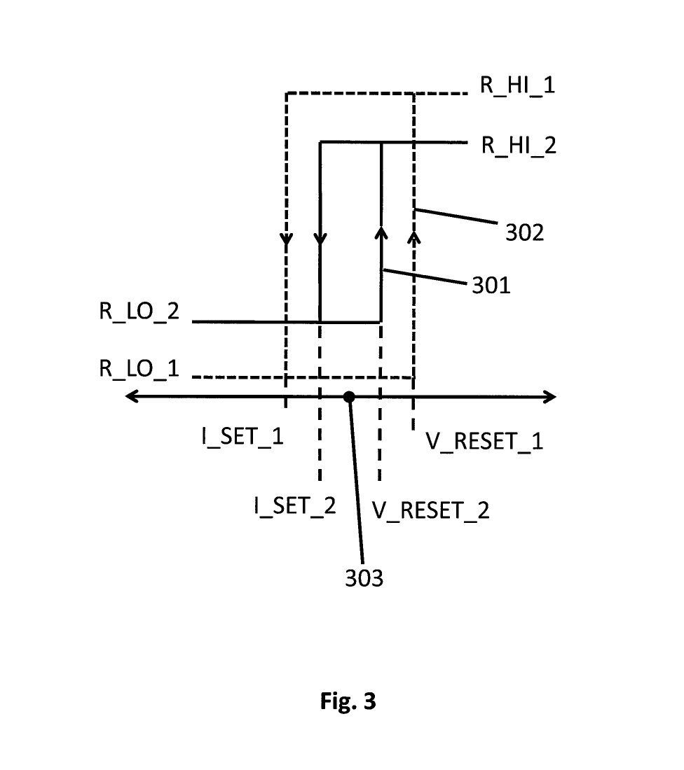

FIG. 3 shows the behavior in more detail. Here, a first hysteresis curve 301 having a smaller RESET voltage (V_RESET_2) and a smaller SET current (I_SET_2) exhibits a smaller high resistance (R_HI_2) and a higher low resistance (R_LO_2) than a second hysteresis curve 302 having larger RESET voltage (V_RESET_1) and larger SET current (I_SET_1) (where “smaller” or “larger” voltage or current is understood to correspond to distance along the horizontal axis from origin 303). Here, if the larger RESET voltage (V_RESET_1) is applied to the resistive element, the storage cell circuit may not be able to apply a large enough SET current (I_SET_1) to switch the state of the resistive element to a low resistance state. Similarly, if the larger SET current (I_SET_1) is applied to the resistive element, the storage cell circuit may not be able to apply a large enough RESET voltage (V_RESET_1) to switch the state of the resistive element to a low resistance state.

Unfortunately, referring to the prior art solution of FIG. 1c, note that a maximum or near-maximum amount of energy is applied to the resistive element during the SET or RESET phases. Specifically, the full logic high voltage is dropped across the BL and SL lines and the access transistor T is kept on during the entirety of the SET phase and the RESET phase. Keeping the access transistor T on for the entirety of these phases has the effect of maximizing the energy that is applied to the resistive element when it switches states.

Further still, recall that during the RESET phase, the access transistor node 101 that is tied directly to the resistive element behaves as the source of the transistor. Here, a “source degenerative” condition can exist at this node 101 where the voltage drop across the resistive element during the RESET phase can adversely affect the source node of the access transistor in the case where the SET operation has caused the resistance element to set with a large resistance.

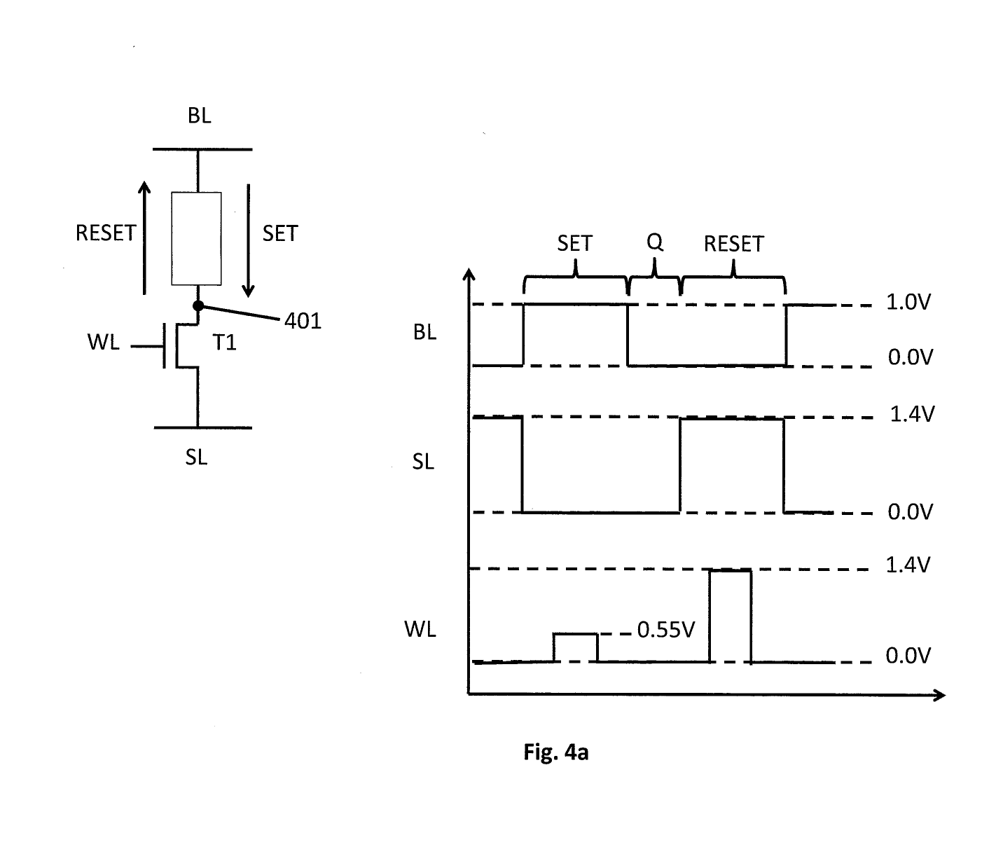

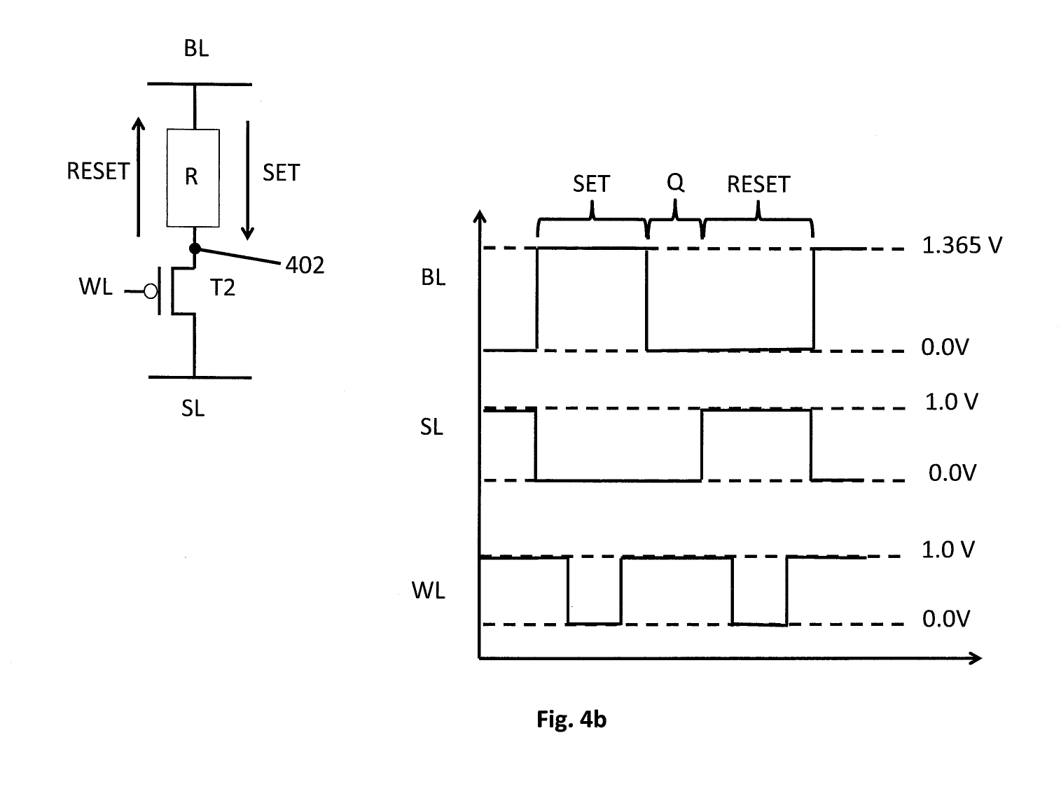

FIG. 4a shows an improved approach that modulates the width of the WL signal in time and the relative voltage levels of the WL, SL and BL lines to substantially avoid setting the resistance of the resistive element too high or too low and/or avoid source degeneration effects. It should be understood that the voltage levels that are depicted in FIG. 4a are only exemplary.

As observed in FIG. 4a, the improved approach narrows the width of the WL signal as compared to the prior art approach observed in FIG. 1c. Here, the narrower WL pulse width limits the amount of time that the access transistor T1 is “on”, which, in turn, essentially limits the amount of time that a SET current or RESET voltage is applied to the resistive element. By limiting the amount of time that the SET/RESET current/voltage is applied, the amount of energy applied to the resistive element during a SET/RESET phase is limited which diminishes the ability of the resistive element to set at too high a resistance during a RESET operation or too low a resistance during a SET operation.

In the embodiment of FIG. 4a the width of the WL pulse is narrowed to be less than the width of the set of respective BL and SL voltages that are applied during a SET or RESET operation. In a further embodiment, this corresponds to narrowing the WL pulse to something less than a SET or RESET cycle time.

FIG. 4a also shows that the relative voltage levels of the WL, BL and SL signals have been modified relative to the prior art approach of FIG. 1c. Specifically, in the prior art approach of FIG. 1c, each of the BL, SL and WL signals have the same high voltage levels and the same low voltage levels. By contrast, in the approach of FIG. 4a, the WL signal has different voltage high levels during the SET and RESET phases. Additionally, the BL and SL signals have different voltage high levels. For example, in one embodiment, as depicted in FIG. 4a, the voltage high level of the BL signal is 1.0 v, the high level signal of the SL signal is 1.4 v and the set of high level voltages for the WL signal is 0.55V (during SET) and 1.4V (during RESET). The low logical level for all three signals is 0.0V. Here, the asymmetrical voltage high levels during the SET and RESET phases provide controllability of write RRAM resistive states.

That is, the use of the different voltage levels as described above helps diminish source degeneration effects in situations where they might otherwise be more problematic. In particular, as described in more detail further below, the circuit of FIG. 4a is more susceptible to source degeneration effects during the RESET phase than during the SET phase. Having a wider voltage difference between the SL and BL signal lines, also as described in more detail below, helps mitigate source degeneration effects. As such, as observed in FIG. 4a, a wider voltage difference between the BL and SL lines is observed during the RESET phase than during the SET phase. That is, using the voltage levels mentioned in the preceding paragraph, during the RESET phase the BL/SL difference is 1.4V ((SL=1.4V)−(BL=0.0V)=1.4V), whereas, during the SET phase the difference is 1.0V ((BL=1.0V)−(SL=0.0V)=0.0V).

The wider BL/SL voltage difference during the RESET phase gives the circuit more “headroom” in case the voltage drop across the resistive element is too large during RESET.

During RESET, in view of the direction of the current flow and the use of an N type access transistor T1, the source of the access transistor T1 corresponds to the node 401 of the access transistor T1 that is directly tied to the resistive element. Here, the access transistor T1 is pushing current up through the resistive element.

The corresponding voltage drop across the resistance element raises the voltage on node 401. If the voltage drop across the resistive element becomes too large, the source voltage of the access transistor may rise to a level that brings the gate-source voltage of the access transistor T1 to a level that is too small to turn-off which will prevent the resistive element from being properly RESET (not enough current will be pushed through the resistive element to flip its resistive state). The larger SL voltage during RESET (1.4V) permits the WL gate voltage of the access transistor to be equally high (1.4V). The higher WL voltage thus provides some “headroom” on the gate voltage in case the source voltage on node 401 rises in view of the current being driven up through the resistive element.

In the case of a SET operation, the WL voltage level is noticeably reduced as compared to its level during a RESET operation because source degeneration effects are not really a concern. In the case of a SET operation, given the direction of the current flow and the use of an N type access transistor T1, the source of the access transistor T1 corresponds to the SL node. Because the SL voltage is fixed, there should be no appreciable increase in source voltage during the SET operation and the WL voltage need only be high enough to keep the access transistor T1 sufficiently “on” (0.55V), while providing the required I_SET to set to the low resistive state without overset. As such, source degeneration effects should be minimal. For these reasons the BL/SL voltage spread can be narrower during the SET phase than during the RESET phase. As such, again using the aforementioned voltages, the BL/SL voltage difference is 1.0V ((BL=1.0V)−(SL=0.0V)=1.0V) whereas as described at length just above during the RESET phase it is 1.4V.

A possible concern with the approach of FIG. 4a is the need to generate three difference voltage levels (0.55V, 1.0V and 1.4V) which may add to the cost and complexity of implementing the circuit.

FIG. 4b shows an improved circuit that embraces some of the same concepts discussed above with respect to FIG. 4a but employs fewer voltage levels (1.365 V and 1.0V). Notably, the access transistor T2 in the approach of FIG. 4b is a P type device rather than an N type device (as presented in FIG. 4a). Like the approach of FIG. 4a, the approach of FIG. 4b narrows the width of the WL signal during the SET and RESET phases to mitigate the propensity of the circuit to SET the resistive element to too low a resistance or RESET the resistive element to too high a resistance. Note that the P type access transistor is “on” when it receives a low voltage level (0.0V).

Because of the presence of the P type device, source degeneration effects are more of an issue during the SET phase than during the RESET phase. Here, given the direction of the current flow and the use of the P type device, node 402 corresponds to the source of the access transistor T2 during the SET phase. During the SET phase, the voltage on node 402 needs to stay sufficiently higher than the WL gate voltage to prevent a pinch-off or near pinch-off of the access transistor T2. In order to ensure such “headroom”, the BL/SL voltage difference is greater during the SET phase than during the RESET phase. That is, during the SET phase, the BL/SL voltage difference is 1.365 V ((BL=1.365)−(SL=0.0V)=1.365), whereas, during the RESET phase the BL/SL voltage difference is only 1.0 V ((SL=1.0V)−(BL=0.0V)=1.0V). During the both the SET and RESET phases the WL gate voltage need only be 0.0V to ensure the access transistor is “on”. Again these specific voltage levels are only exemplary.

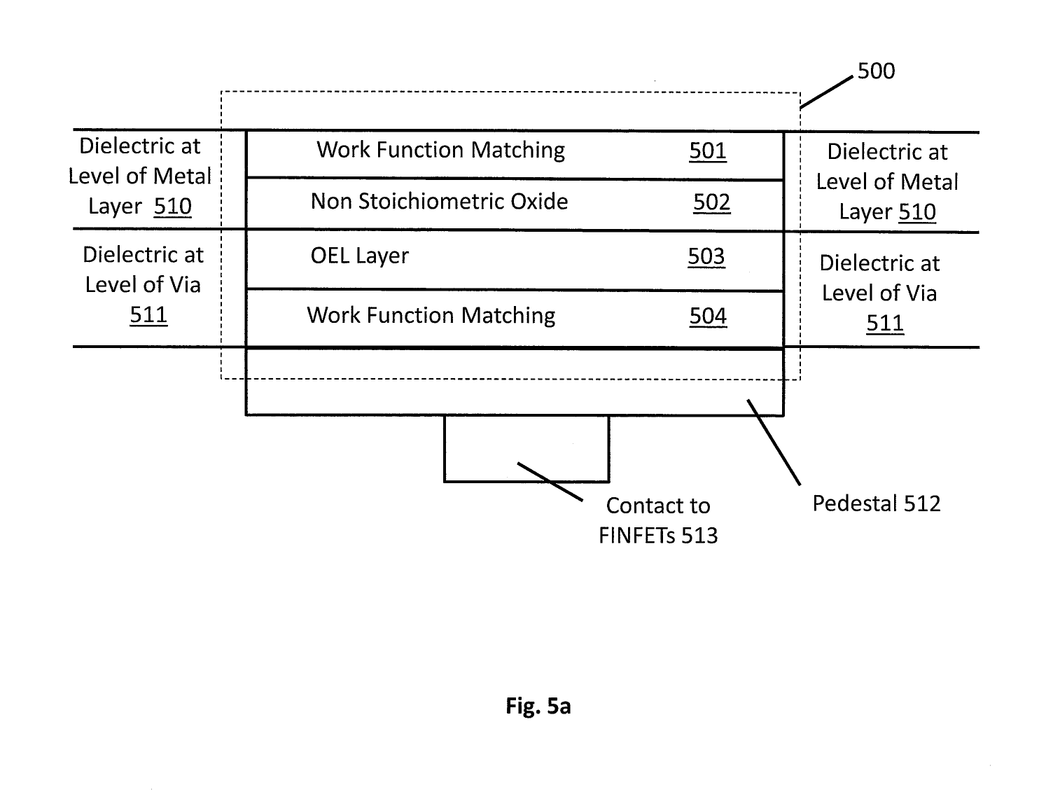

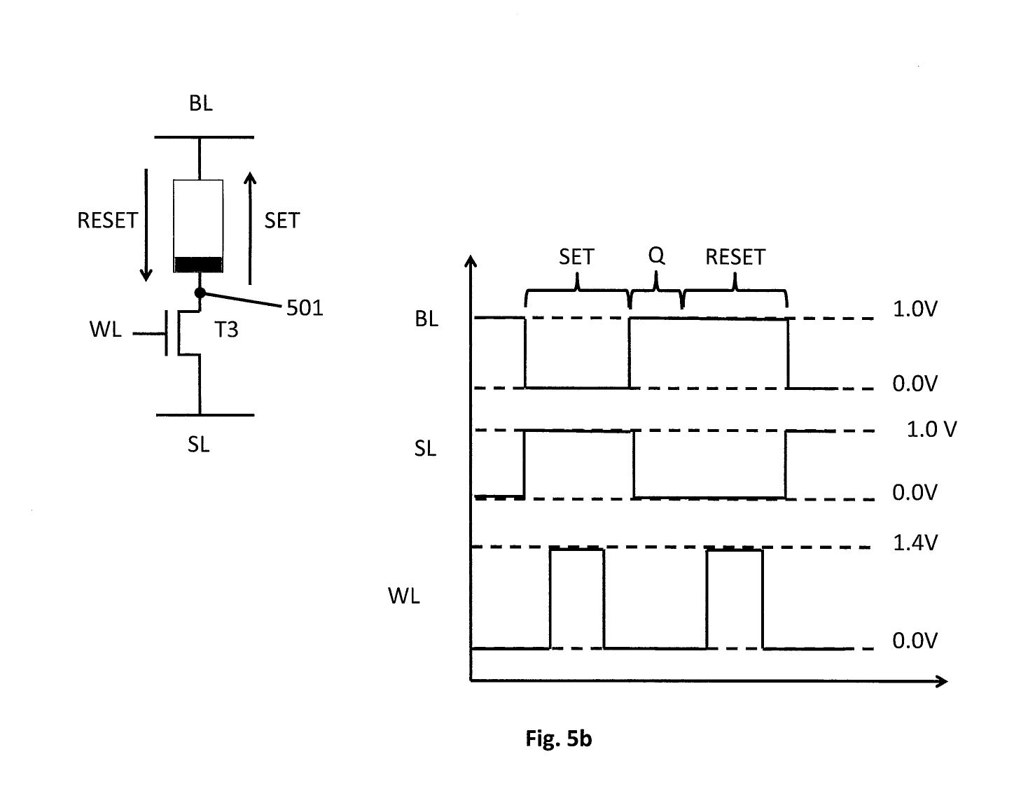

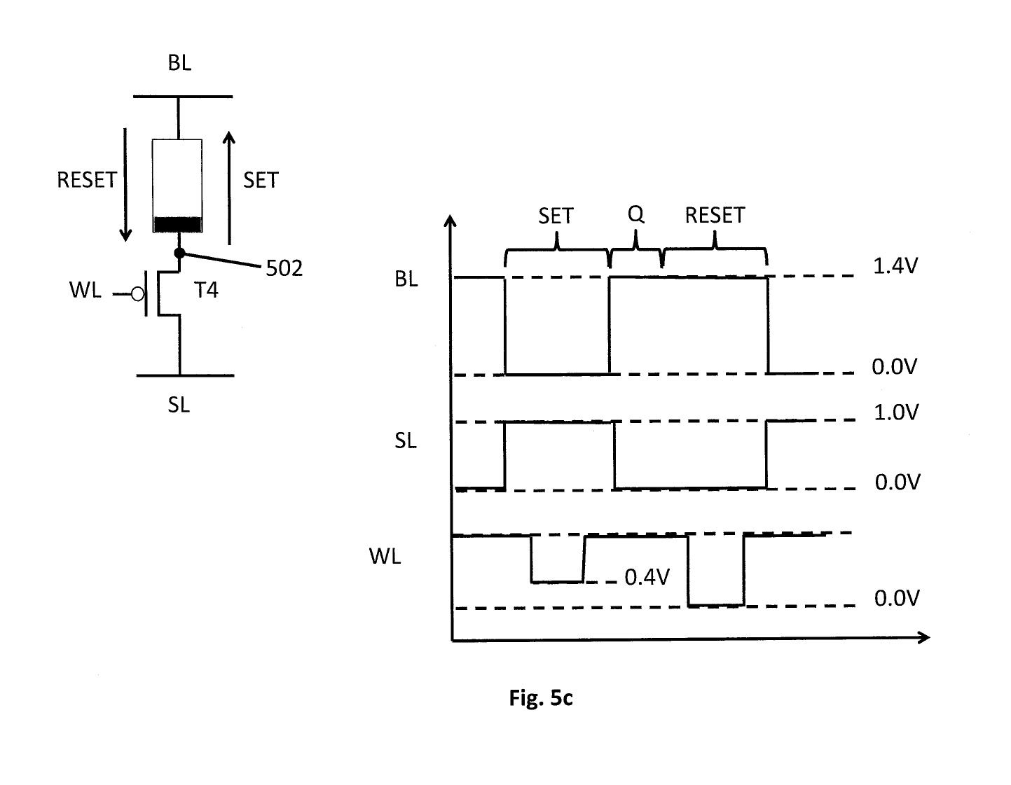

FIG. 5a shows another resistive element structure 500 that is different than the prior art resistive element structure 200 discussed above in FIG. 2. As observed in FIG. 5a, the OEL layer 503 is toward the bottom of the multi-layer stack 500 rather than toward the top of the stack 200 as observed in FIG. 2. With the OEL layer 503 toward the bottom of the stack, the polarity of the resistive element 500 is opposite that of the prior art resistive element 200. That is, whereas in the prior art resistive element stack 200 of FIG. 2, the direction of the SET current is down through the stack and the direction of the RESET current is up through the stack, by contrast, in the new stack structure 500 observed in FIG. 5a the SET current direction is up through the stack and the RESET current direction is down through the stack. Note that the manufacture of the stack 500 includes forming an OEL layer 503 and then forming a non stoichiometric layer 502 over the OEL layer 503.

Additionally, the height of the resistive element stack 500 corresponds to the thickness of a single lower metal layer dielectric 510 and a single lower via layer dielectric 511, such as the M2 metal and immediately lower (M1 via) dielectric layers (rather than through multiple lower metal layers and multiple lower dielectric layers, or a single upper metal and dielectric layer (such as observed 210 in FIG. 2)). The usage of the single, lower metal layer dielectric 510 and the single lower via layer dielectric 511 reduces both the height and the feature size of the resistive element stack compared to the prior art approach of FIG. 2. Hence, the feature size of the resistive element can be comparable to or even smaller than the size of an extremely small transistor (e. g FINFET) to which the resistive element is to make contact. As such, a conductive (e.g., metal) pedestal structure 512 is formed beneath the resistive element stack 500 and serves to support the resistive element stack 500 as it makes contact to an extremely small access transistor, such as a FINFET access transistor, having an extremely small contact 513. The material composition of the different layers of the stack 500 of FIG. 5 may be the same as those of the stack 200 of FIG. 2. Likewise, optional barrier layers may exist. In an alternate embodiment, the resistive element stack is confined to the metal dielectric layer 510 (as in the approach of FIG. 2) and no pedestal layer exists.

In a further alternate embodiment, a resistive stack having a design where the OEL layer is toward the top, such as the stack design 200 of FIG. 2, may be used in place of the stack 500 of FIG. 5a. In this embodiment, the SET current will flow down through the stack and the RESET current will flow up through the stack. The stack may also consume both metal and via dielectric layers 510, 511 as observed in FIG. 5a. A pedestal 512 for making contact to an extremely small access transistor, such as a FINET, may also exist. In an embodiment, at least when the OEL layer 503 is toward the bottom of the stack, the pedestal may be comprised of tungsten (W) or cobalt (Co) rather than copper (Cu) to prevent any reaction between the pedestal 512 and the OEL layer 503.

In various embodiments, as observed in FIG. 5a, the stack includes an intermediate metal layer 504 having a work function that substantially matches the work function of the pedestal material. Here, the pedestal may be composed of any of Copper, Ruthenium, Tantalum, Tungsten, Nickel Silicon or Cobolt Silicon. In various embodiments the bottom-side OEL layer 503 may be comprised of any of a 5 d transition element and/or an alloy thereof, a 4d transition element and/or an alloy thereof or a 3 d transition element and/or an alloy thereof. In further embodiments the bottom-side OEL layer 503 is doped with any of Aluminum, Indium or Tin. In various embodiments the bottom-side OEL layer 503 is composed of a metal where the metal is compounded with a material that acts as source or sink of metal ions. The compounded material may be any of Oxygen, Sulfur; Selenium or, Tellurium.

FIG. 5b shows another RRAM storage cell that uses a resistive element stack having the OEL layer toward the bottom of the stack (such as the OEL layer 503 in the stack 500 observed in FIG. 5a). Because the OEL layer is on the bottom of the resistive stack, as discussed above with respect to FIG. 5a, the RESET current is pulled down by the access transistor T3 through the resistive element. By contrast, the SET current is pushed up through the resistive element by the access transistor T3.

With the use of an N type access transistor T3, source degeneration effects are more of an issue during the SET phase than during the RESET phase since the N type access transistor T3 is pushing current up through the resistive element during the SET phase. Because the SET phase produces a low resistance state, the voltage rise on node 501 will be minimal which reduces/eliminates source degeneration concerns when the access transistor is driving current up through the resistive element. Eliminated or reduced source degeneration effects on node 501 permits the circuit, unlike the aforementioned circuits of FIGS. 4a and 4b, to be biased without a wider BL/SL voltage. As such, as observed in FIG. 5b, the BL/SL voltage difference is approximately the same for both phases (approximately 1.0V). The circuit of FIG. 5b therefore, like the circuit of FIG. 4b, only really requires two external supply voltages.

FIG. 5c shows another storage cell embodiment having an OEL layer on the bottom resistive element but that uses a P type access transistor T4 rather than an N type access transistor. In the circuit of FIG. 5c, given the current flow direction and use of a P type access transistor T4, source degeneration effects may be a concern in the RESET phase rather than the SET phase. Here, node 502 should stay sufficiently higher than the WL gate voltage to ensure the access transistor T4 remains properly forward biased. As such, a larger BL/SL voltage difference is established for the RESET phase ((BL=1.4V)−(SL=0.0V)=1.4V) than for the SET phase ((SL=1.0V)−(BL=0.0V)=1.0V). During the RESET phase, the WL gate voltage is minimized to 0.0V to ensure the access transistor remains active given the source degeneration effect concerns, whereas, during the SET phase, the WL is raised to 0.4 V because the source node corresponds to the SL node which is fixed at 1.0 V and the access transistor T4 only needs 0.6V of forward bias. Also, for control of the I_SET as well as the low resistive state for SET (as explained in FIG. 3), over-drive of access transistor T4 during SET phase is prevented.

It should be noted that although not shown in FIGS. 4a, 4b, 5b and 5c, circuits exist outside the memory cell to drive the appropriate SL, BL and WL signals including their corresponding voltage levels.

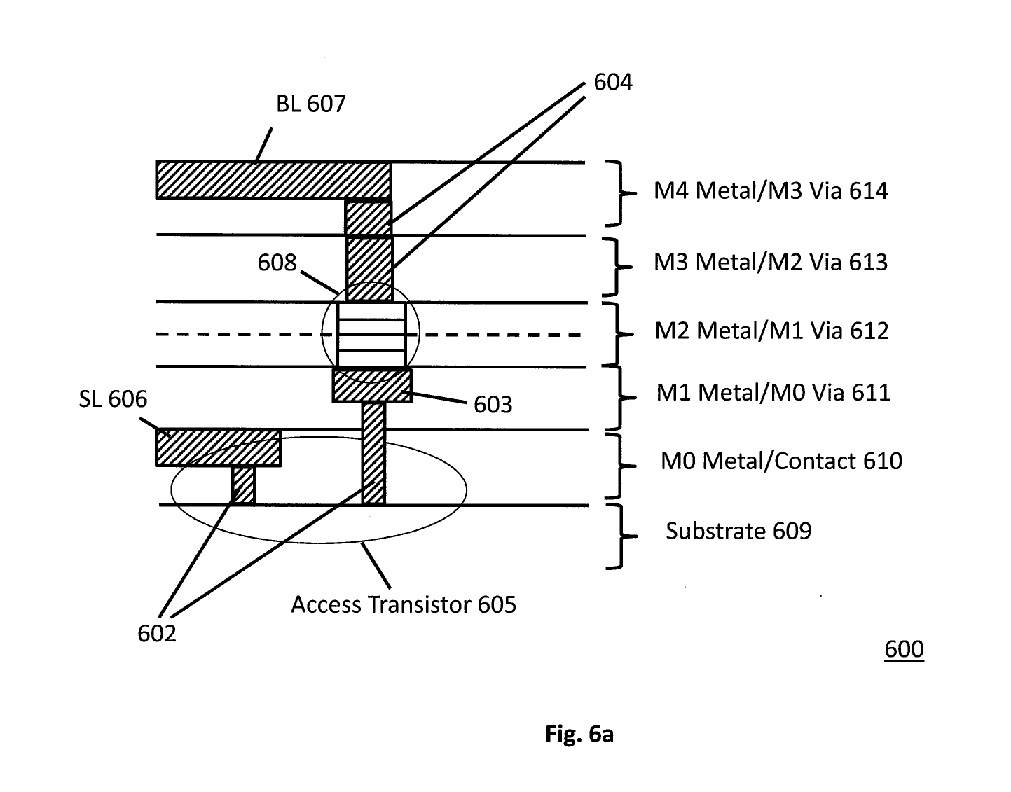

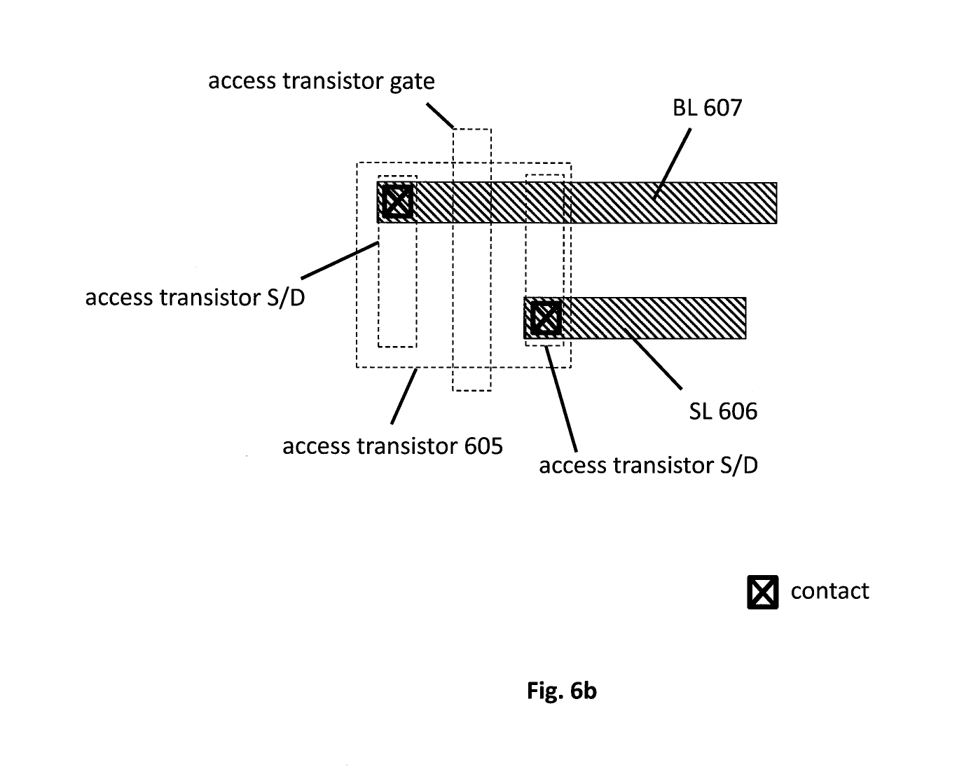

FIGS. 6a and 6b depict more layout details 600 for any of the RRAM circuits discussed above. As observed in FIG. 6a, the resistive element 608 may be located in the M2 metal and M1 via layers 612. The aforementioned pedestal 603 may be formed directly beneath the resistive element 608 using M1 metal. Contacts 602 to the access transistor 605 are formed in the M0 layer 610 with the contact to the pedestal 603 extending through the via layer of the M1 layer 611. For simplicity the contact to the gate of the transistor 605 (the word line WL) is not shown in FIG. 6a but in various embodiments it can be formed in the M0 layer 610. Wider vias 604 are shown connecting the top of the resistive element 608 to the BL line 607 which is formed in the M4 layer 614. One of the contacts 605 with the access transistor 605 is connected to the SL line 606 which is formed in the M0 layer. Forming the BL line 607 in the M4 layer instead of the M3 layer keeps the BL line 607 in parallel with the SL line 606, as described herein.

A pertinent part of the design of the layout of FIG. 6 is that, neighboring metal lines typically run orthogonal to one another. As such, metal lines of alternating metal layers run parallel to one another. As such, for example, metal lines formed in the M0, M2 and M4 layers 610, 612 and 614 run parallel to one another and perpendicular to metal lines formed in the M1 and M3 layers. With the SL and BL lines 606, 607 being formed to run parallel to one another, it is easier to make them of equal length or near equal length. As such, their inherent resistances will be comparable if not equal or near equal. Having comparable inherent resistances for the SL and BL lines enables differential read and/or write processes to the storage cell 608. FIG. 6b shows a top down view of the layout of FIG. 6a. Here, note that the SL and BL lines 606, 607 extend to opposite regions (e.g., corners) of the approximate surface area consumed by the access transistor 605.

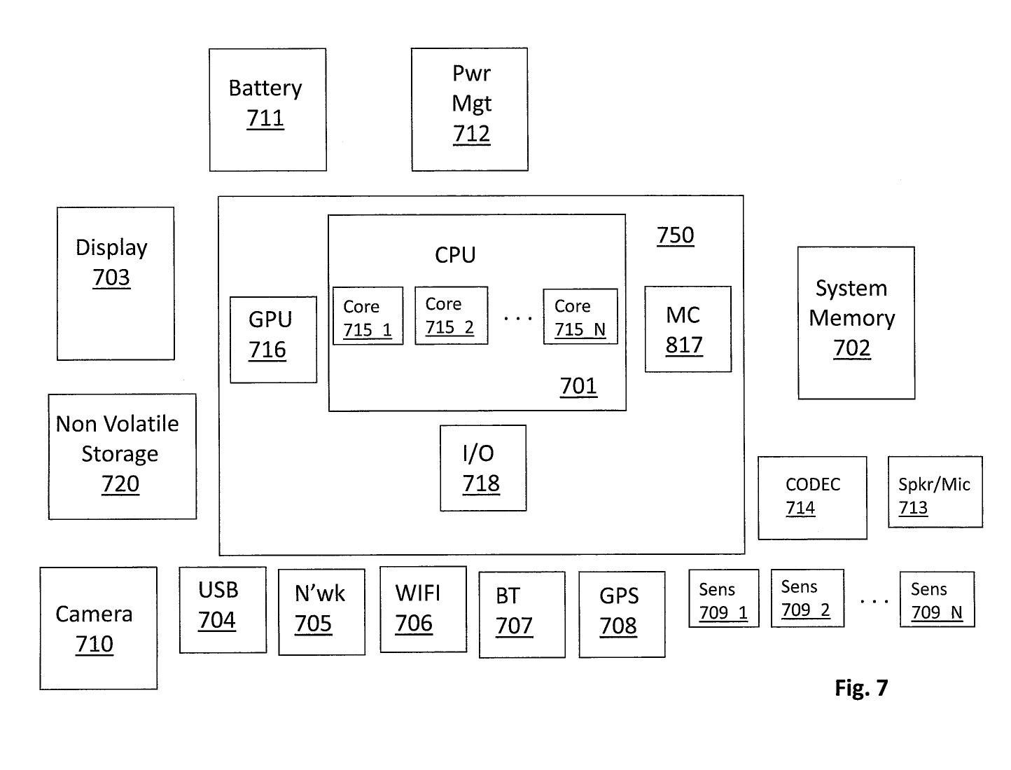

FIG. 7 shows a depiction of an exemplary computing system 700 such as a personal computing system (e.g., desktop or laptop) or a mobile or handheld computing system such as a tablet device or smartphone, or, a larger computing system such as a server computing system.

As observed in FIG. 7, the basic computing system may include a central processing unit 701 (which may include, e.g., a plurality of general purpose processing cores and a main memory controller disposed on an applications processor or multi-core processor), system memory 702, a display 703 (e.g., touchscreen, flat-panel), a local wired point-to-point link (e.g., USB) interface 704, various network I/O functions 705 (such as an Ethernet interface and/or cellular modem subsystem), a wireless local area network (e.g., WiFi) interface 706, a wireless point-to-point link (e.g., Bluetooth) interface 707 and a Global Positioning System interface 708, various sensors 709_1 through 709_N (e.g., one or more of a gyroscope, an accelerometer, a magnetometer, a temperature sensor, a pressure sensor, a humidity sensor, etc.), a camera 710, a battery 711, a power management control unit 712, a speaker and microphone 713 and an audio coder/decoder 714.

An applications processor or multi-core processor 750 may include one or more general purpose processing cores 715 within its CPU 701, one or more graphical processing units 716, a memory management function 717 (e.g., a memory controller) and an I/O control function 718. The general purpose processing cores 715 typically execute the operating system and application software of the computing system. The graphics processing units 716 typically execute graphics intensive functions to, e.g., generate graphics information that is presented on the display 703. The memory control function 717 interfaces with the system memory 702. The system memory 702 may be a multi-level system memory having a level that includes an emerging (e.g., three dimensional, crosspoint) non volatile memory technology that includes RRAM cells such as the RRAM cells discussed above.

Each of the touchscreen display 703, the communication interfaces 704-707, the GPS interface 708, the sensors 709, the camera 710, and the speaker/microphone codec 713, 714 all can be viewed as various forms of I/O (input and/or output) relative to the overall computing system including, where appropriate, an integrated peripheral device as well (e.g., the camera 710). Depending on implementation, various ones of these I/O components may be integrated on the applications processor/multi-core processor 750 or may be located off the die or outside the package of the applications processor/multi-core processor 750.

Embodiments of the invention may include various processes as set forth above. The processes may be embodied in machine-executable instructions. The instructions can be used to cause a general-purpose or special-purpose processor to perform certain processes. Alternatively, these processes may be performed by specific hardware components that contain hardwired logic for performing the processes, or by any combination of programmed computer components and custom hardware components.

Elements of the present invention may also be provided as a machine-readable medium for storing the machine-executable instructions. The machine-readable medium may include, but is not limited to, floppy diskettes, optical disks, CD-ROMs, and magneto-optical disks, FLASH memory, ROMs, RAMs, EPROMs, EEPROMs, magnetic or optical cards, propagation media or other type of media/machine-readable medium suitable for storing electronic instructions. For example, the present invention may be downloaded as a computer program which may be transferred from a remote computer (e.g., a server) to a requesting computer (e.g., a client) by way of data signals embodied in a carrier wave or other propagation medium via a communication link (e.g., a modem or network connection).

In the foregoing specification, the invention has been described with reference to specific exemplary embodiments thereof. It will, however, be evident that various modifications and changes may be made thereto without departing from the broader spirit and scope of the invention as set forth in the appended claims. The specification and drawings are, accordingly, to be regarded in an illustrative rather than a restrictive sense.

1.-14. (canceled)

15. An apparatus, comprising:
a resistive random access memory cell having a storage cell comprising a bottom-side OEL layer, said bottom side OEL layer residing at a same vertical level as a via layer.

16. The apparatus of claim 15 wherein the storage cell comprises a vertical height that is aligned with a metal layer's vertical height and the via layer's vertical height, the metal layer formed on the via layer.

17. The apparatus of claim 15 further comprising a pedestal beneath the storage cell.

18. The apparatus of claim 17 further comprising an intermediate metal layer, the intermediate metal layer having a work function that substantially matches the work function of the pedestal's material.

19. The apparatus of claim 17 wherein the pedestal is comprised of any of the following:
Copper;
Ruthenium;
Tantalum;
Tungsten;
Nickel Silicon;
Cobolt Silicon.

20. The apparatus of claim 15 wherein the bottom-side OEL layer is comprised of any of:
a 5d transition element and/or an alloy thereof;
a 4d transition element and/or an alloy thereof;
a 3d transition element and/or an alloy thereof;

21. The apparatus of claim 20 wherein the bottom-side OEL layer is doped with any of:
Aluminum;
Indium;
Tin.

22. The apparatus of claim 15 wherein the bottom-side OEL layer is comprised of a metal, the metal being compounded with a material to act as source or sink of metal ions, the material being any of:
Oxygen;
Sulfur;
Selenium;
Tellurium.

23. The apparatus of claim 15 further comprising a smaller contact beneath the pedestal that electrically connects the pedestal to a FINFET transistor.

24.-29. (canceled)
